(19) United States
(12) Patent Application Publication
(10) Pub. No.: US 2015/0228510 A1
(43) Pub. Date: Aug. 13, 2015

(54) WHIPSAW USED IN WAFER CLEANING

(71) Applicant: Kingyoup Optronics Co., Ltd., New Taipei (CN)

(72) Inventors: Chih-Chung WU, New Taipei (CN); Chang-Pei Ou, New Taipei (CN); Feng-Po Liang, New Taipei (CN); Chih-Yang Lee, New Taipei (CN)

(73) Assignee: Kingyoup Optronics Co., Ltd., New Taipei (CN)

(21) Appl. No.: 14/179,213

(22) Filed: Feb. 12, 2014

(51) Int. Cl. H01L 21/67

(52) U.S. Cl. CPC H01L 21/67057

(57) ABSTRACT

A whipsaw for carrying a wafer in wafer cleaning is disclosed. The whipsaw may include a cleaning tank, an annular groove around a peripheral of the cleaning tank, a discharge chute disposed between the cleaning tank and the annular groove, at least one first flow channel communicative of the cleaning tank and the discharge chute, and at least one second flow channel communicative of the annular groove and the discharge chute. When the wafer with a tape is placed in the whipsaw, the wafer may correspond to the cleaning tank, and a portion of the tape unmasked by the wafer may correspond to the annular groove. The first flow channel provides a first fluid into the cleaning tank with the first fluid cleaning the wafer, and the second flow channel provides a second fluid into the annular groove with the second fluid isolating the first fluid from the tape.

### BACKGROUND

1. Technical Field

The present disclosure relates to a whipsaw, and more particularly, to a whipsaw used in wafer cleaning.

2. Description of Related Art

In a typical integrated circuit (IC) manufacturing process, wafer cleaning could be repeated most often, which could suggest its importance and criticality to the yield of the wafer manufacturing. The wafer cleaning could be needed in both the early stages and the late stages of the wafer manufacturing. Since every wafer manufacturing/processing step may be associated with its potential sources of contamination, which could render defective the wafer and cause the components produced based on such wafer to malfunction. The main purpose of the wafer cleaning is to remove metal impurities on the wafer surface and contamination of organic compounds and prevent the deposit of particles such as dust.

At the time the wafer cleaning is to be preformed, the back surface of the wafer could be glued to a tape, which facilitates the placement of the wafer in an annular frame. When the annular frame is secured to a wafer hold, the wafer hold could be driven by a motor so that the wafer hold could rotate along with the wafer. Chemicals or de-ionized water (DIW) thereafter could be outputted through a nozzle and the rotating wafer may ensure the chemicals or DIW could be spread onto the entire surface of the wafer. However, since only one set of the nozzle is used for the wafer cleaning coupled with the nozzle's inherent limited cleaning coverage the nozzle is required to move outwardly to clean the surface away from the center of the wafer. At the time of the nozzle moves at a constant speed between the peripheral and the center of the wafer, the cleaning performance may be negatively affected especially for the area away from the center of the wafer. To improve the performance of the cleaning, the time for the nozzle to operate may increase, reducing the throughput of the wafer manufacturing.

Furthermore, the above-mentioned wafer cleaning approach generally has no control over where the chemicals or DIW could travel. Consequently, the chemicals or DIW may damage the tape, resulting in the contamination on the tape. Therefore, the conventional wafer cleaning approach relying on the rotation of the wafer is not satisfactory in terms of the cleaning efficiency and the tape susceptible to the contamination.

### SUMMARY

The present disclosure provides a whipsaw used in the wafer cleaning for addressing the problems of the cleaning inefficiency and the tape being susceptible to the damage or contamination.

The disclosed whipsaw for carrying the wafer in the wafer cleaning, where a tape is attached with the wafer when the wafer is placed within a frame. The whipsaw may include a cleaning tank, an annular groove around a peripheral of the cleaning tank, a discharge chute disposed between the cleaning tank and the annular groove, at least one first flow channel communicative of the cleaning tank and the discharge chute, and at least one second flow channel communicative of the annular groove and the discharge chute. When the wafer with the tape is placed in a frame, which is further placed in the whipsaw, the wafer may correspond to the cleaning tank, and a portion of the tape unmasked by the wafer may correspond to the annular groove. The first flow channel provides a first fluid into the cleaning tank with the first fluid cleaning the wafer, and the second flow channel provides a second fluid into the annular groove with the second fluid isolating the first fluid from the tape.

Since the wafer and the tape overlap the whipsaw, the wafer may cover the opening of the cleaning tank and the tape portion unmasked by the wafer covers the notch of the annular groove. And the first fluid in the cleaning tank is used to clean the surface of the wafer, while the second fluid in the annular groove is used to isolate the first fluid from the edge of the wafer. Thus, the first fluid may be prevented from reaching the tape or thereafter causing the contamination on the tape. Therefore, the efficiency of the cleaning may improve and the tape may not be damaged or contaminated.

For further understanding of the present disclosure, reference is made to the following detailed description illustrating the embodiments and examples of the present disclosure. The description is only for illustrating the present disclosure, not for limiting the scope of the claim.

### BRIEF DESCRIPTION OF THE DRAWINGS

The drawings included herein provide further understanding of the present disclosure. A brief introduction of the drawings is as follows:

FIG. 1 shows a schematic diagram of a whipsaw according to one embodiment of the present disclosure;

FIG. 2 shows a cross-sectional view of the whipsaw embodiment in FIG. 1 according to one embodiment of the present disclosure;

FIG. 3 shows a cross-sectional view of the whipsaw embodiment in FIG. 1 according to one embodiment of the present disclosure;

FIG. 4 shows an enlarged view of a certain cross section of the whipsaw embodiment in FIG. 1 according to one embodiment of the present disclosure;

FIG. 5 shows the cross section of the whipsaw embodiment in FIG. 1 when in use according to one embodiment of the present disclosure;

FIG. 6 shows a schematic diagram of another whipsaw according to another embodiment of the present disclosure;

FIG. 7 shows a cross-sectional view of the whipsaw embodiment in FIG. 6 according to one embodiment of the present disclosure;

FIG. 8 shows a cross-sectional view of the whipsaw embodiment in FIG. 6 according to one embodiment of the present disclosure;

FIG. 9 shows an enlarged view of a certain cross section of the whipsaw embodiment in FIG. 6 according to one embodiment of the present disclosure; and

FIG. 10 shows the cross section of the whipsaw embodiment in FIG. 6 when in use according to one embodiment of the present disclosure;

### DESCRIPTION OF THE EXEMPLARY EMBODIMENTS

The aforementioned and other technical contents, features, and efficacies will be shown in the following detail descriptions of a preferred embodiment corresponding with the reference figures.

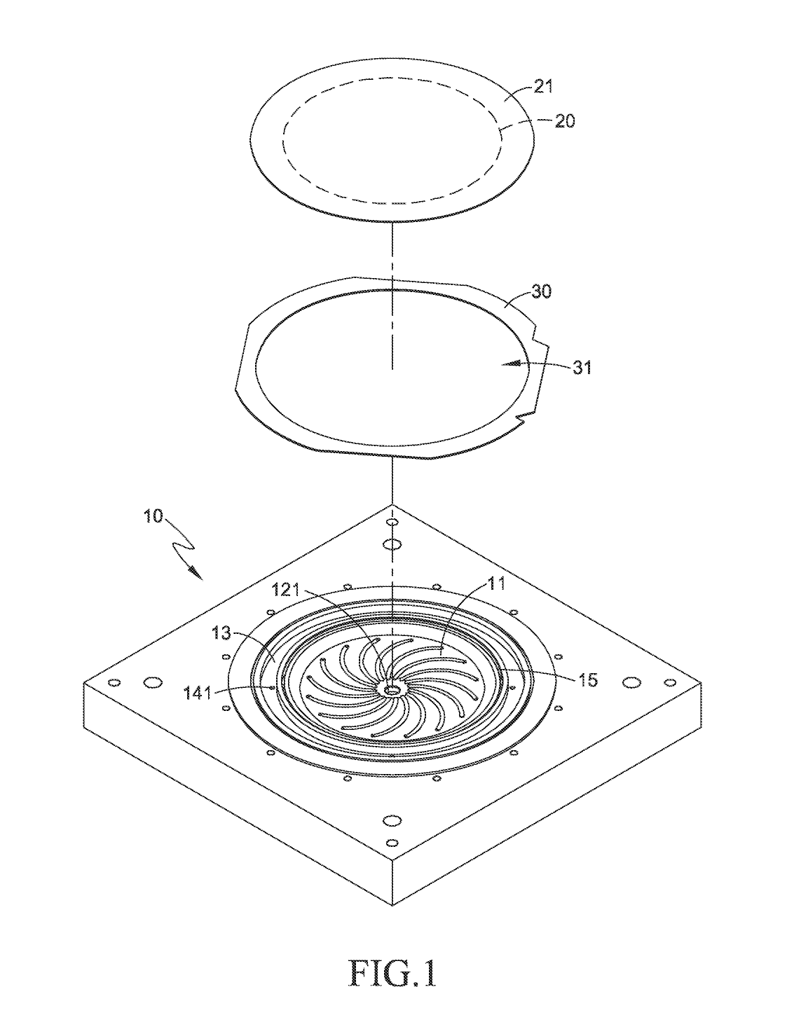

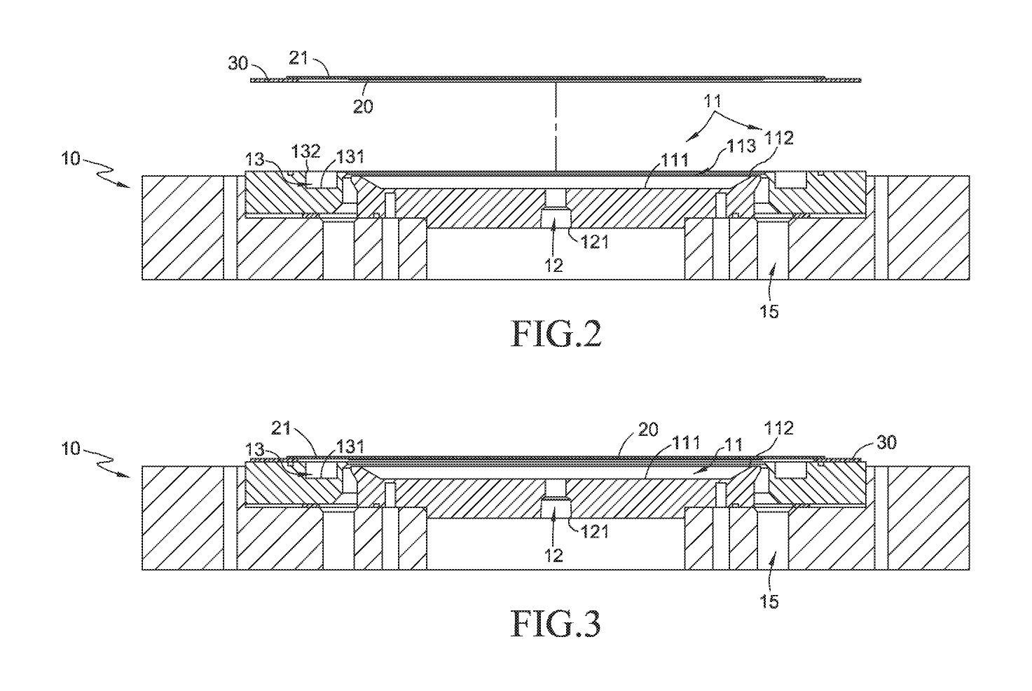

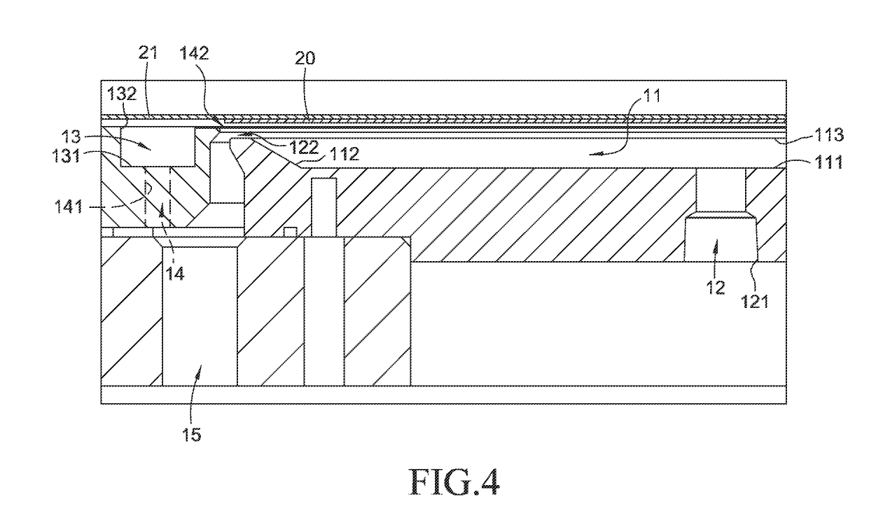

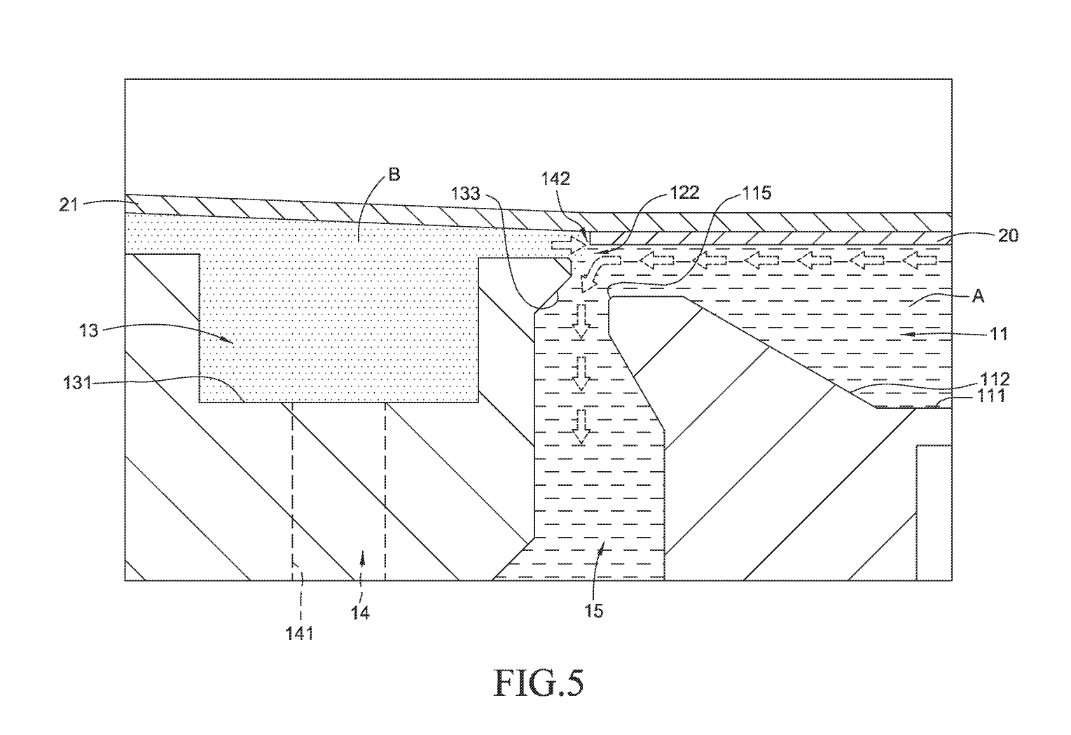

Please see FIGS. 1-5. FIG. 1 shows a schematic diagram of a whipsaw according to one embodiment of the present disclosure. FIGS. 2 and 3 are cross-sectional diagrams of the whipsaw embodiment in FIG. 1. FIG. 4 is an enlarged schematic diagram of a cross-sectional portion of the whipsaw embodiment in FIG. 1. FIG. 5, meanwhile, shows a schematic diagram of a cross-sectional portion of the whipsaw embodiment in FIG. 1 when in use.

A whipsaw 10 according to the present disclosure may be used in a wafer cleaning process to carry a wafer 20. One side of the wafer 20 may be equipped with a tape 21 for positioning the wafer 20 within an accommodating space 31 of a frame 30. It is worth noting that approaches enabling the wafer 20 to be placed within the frame 30 have been known among the artisans in the pertinent field of the art.

The whipsaw disc 10 may include a cleaning tank 11 defining a bottom surface 111 and a guide slope 112 surrounding the bottom surface 111. And the cleaning tank 11 may include an opening 113 at a side opposite from the bottom surface 111. The cleaning tank 11 may be in the divergent shape beginning from the bottom surface 111 to the opening 113, so that the outer diameter of the guide slope 112 may be larger than the outer diameter of the bottom surface 111. One advantage of the guide slope 112 being divergent in shape is at the time a first liquid A is injected into the cleaning tank 11 the first liquid A may be guided to the opening 113 along the guide slope 112 more efficiently. Another advantage of the guide slope 112 being divergent in shape is ensures the first liquid A may fully fill up the cleaning tank 11, preventing the air from residing in the cleaning tank 11, by reducing the area of the cross section of the cleaning tank 11 so that no structural dead zone may exist in the cleaning tank 11.

Furthermore, the whipsaw 10 may include a first flow channel 12 including a first inlet 121 and a first outlet 122. The first inlet 121 may be disposed in the bottom surface 111 of the cleaning tank 11, allowing for the first fluid A to be flown into the cleaning tank 11. It should be noted that the first inlet 121 may be placed at the center of the cleaning tank 11, though the number and the position of the first inlet 121 is not therefore limited. In other words, the first inlet 121 may be disposed at the location of the cleaning tank 11 other than the center thereof. For example, multiple first inlets 121 may surround the bottom surface 111. The first outlet 122 may be formed at a terminal of the guide slope 112. Similarly, the number and the location of the first outlet 122 may vary from case to case. In one implementation, the first outlets 122 may surround the guide slope 112 of the cleaning tank 11.

In the embodiments of the present disclosure, the cleaning tank 11 may further include a plurality of guide grooves 114. The guide groves 114 may be arranged along the radial direction from the first inlet 121. And each guide groove 114 may be in a spiral shape. Accordingly, the guide grooves 114 may increase the pressure and the speed when the first liquid A flows over the course of being guided by the guide grooves 114. Consequently, the efficiency of the first liquid A cleaning the wafer 20 may improve.

Moreover, the whipsaw 10 may further include an annular groove 13 surrounding the peripheral of the cleaning tank 11. The annular groove 13 may also define a bottom surface 131 and have a notch 132 formed at the side opposite from the bottom surface 131. The whipsaw 10 may also include a second flow channel 14 including a second inlet 141 and a second outlet 142. The second inlet 141 may be disposed on the bottom surface 131 of the annular groove 13, but not limited thereto. The second inlet 141 may enable a second fluid B to be flown into the annular groove 13. It should be noted that the number of the second inlets 141 may vary from case to case. The second outlet 142 may be formed in the proximity of the notch 132 of the annular groove 13. For example, the second outlets 142 may surround the notch 132 of the annular groove 13. Meanwhile, the second outlet 142 may be located at an edge of the wafer 20.

The whipsaw 10 may further include a discharge chute 15 disposed within the whipsaw 10 and between the cleaning tank 11 and the annular groove 13, enabling the first flow channel 12 to be communicative of the cleaning tank 11 and the discharge chute 15 and the second flow channel to be communicative of the annular groove 13 and the discharge chute 15. It should be noted that, in this embodiment the first outlet 122 of the first flow channel 12 may be communicative of the second outlet 142 of the second flow channel 14.

When the frame 30 is positioned in the whipsaw 10, the wafer 20 may mask the opening 113 and correspond to the cleaning tank 11 while the tape 21 unmasked by the wafer 20 may correspond to the annular groove 13. More specifically, the wafer 20 and the tape 21 may cover the whipsaw 10, so that the wafer 20 may mask the opening 113 of the cleaning tank 11 and the tape 21 may mask the notch 132 of the annular groove 13. When the first fluid A (such as a cleaning solution, but not limited thereto) enters into the cleaning tank 11 through the first inlet 121, the first fluid A may fully fill up the cleaning tank 11 and allows for the entire surface of the wafer 20 to be cleaned. It should be noted that when the first inlet 121 is placed at the center of the cleaning tank 11 the first fluid A when pressurized at one high pressure may be employed to directly wash the center of the wafer 20 and may be guided along the surface of the wafer 20 in the radial direction to the edge of the wafer 20, before being transmitted to the discharge chute 15 through the first outlet 122. With this arrangement, the surface of the wafer 20 may be fully cleaned by the first fluid A.

When the wafer 20 is in the cleaning process, to avoid the tape 21 from being contaminated by the first fluid A the second fluid B (such as high-pressurized air or water, but not limited thereto) may be driven from the second inlet 141 into the annular groove 13, so that the second fluid B may be discharged from the second outlet 142. Because the first outlet 122 may be communicative of the second outlet 142, by controlling the pressure of the second fluid B to maintain the second fluid B at the junction of the tape 21 and the wafer 20 the first fluid A may be isolated from the tape 21. Thus, despite the first liquid A may flow to the first outlet 122 in a radial manner along the surface of the wafer 20 the high-pressurized second fluid B may function to isolate the first fluid A from the tape 21 at the edge of the wafer 20. Also, the first fluid A may be flown to the discharge chute 15 to be recycled. The first fluid A after going through the corresponding recycling process (such as filtering) may be re-injected into the first flow channel 12 to be used in another wafer cleaning operation for another wafer.

Please refer to FIG. 5 illustrative of the top portion of the outer wall of the cleaning tank 11 having a beveled guide 115, which may surround the peripheral of the cleaning tank 11. And the outer wall of the annular groove 13 may be equipped with a stop surface 133 corresponding to the beveled guide 115. As such, when the first fluid A flows through the first outlet 122 horizontally the beveled guide 115 may be used to guide the first fluid downwardly and the stop surface 133 may be used to prevent the first fluid A from being reversed to the second outlet 142, or minimize the potential direct impact of the first fluid A on the second outlet 142. And the second outlet 142 may be located higher than the first outlet 122, coupled with the presence of the high-pressurized second fluid B to block or isolate the first fluid A from the tape 21, the tape 21 may not be damaged or contaminated by the first fluid A and the first fluid A may be effectively guided to the discharge chute 15.

Plus, without negatively affecting the wafer cleaning process, another element (not shown) may be used to apply a predetermined pressure onto the wafer for causing the wafer to somewhat tilt downwardly. Therefore, the tape 21 unmasked by the wafer 20 may be tilted with a tilt angle (as shown in FIG. 5). Consequently, with the tilt angle when the first fluid A flows to the edge of the wafer edge 20 the first fluid A may not directly flow to the tape 21, thus providing another layer of the protection with the tape 21.

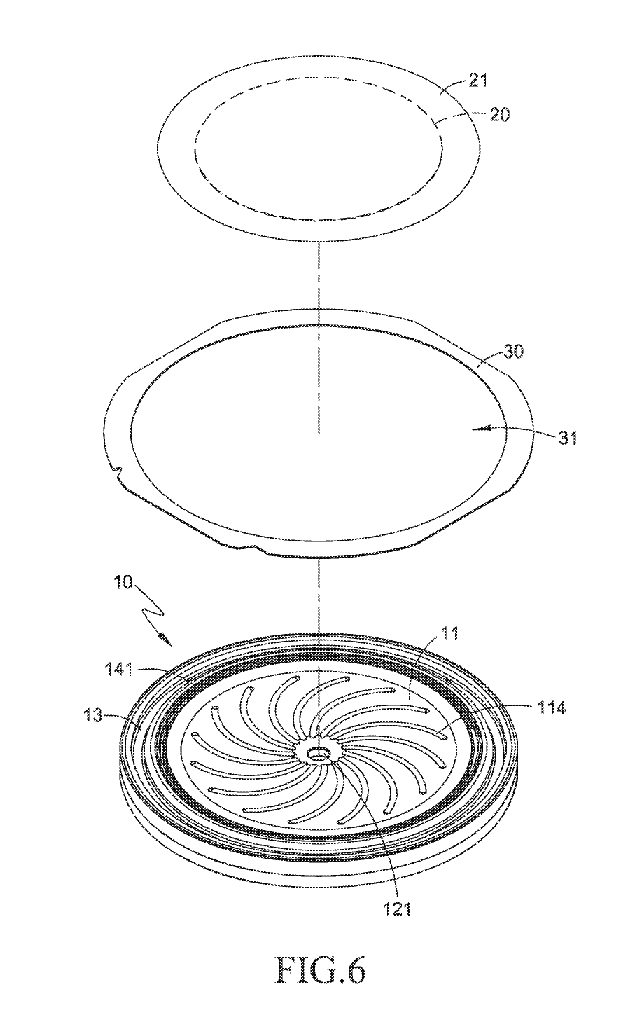

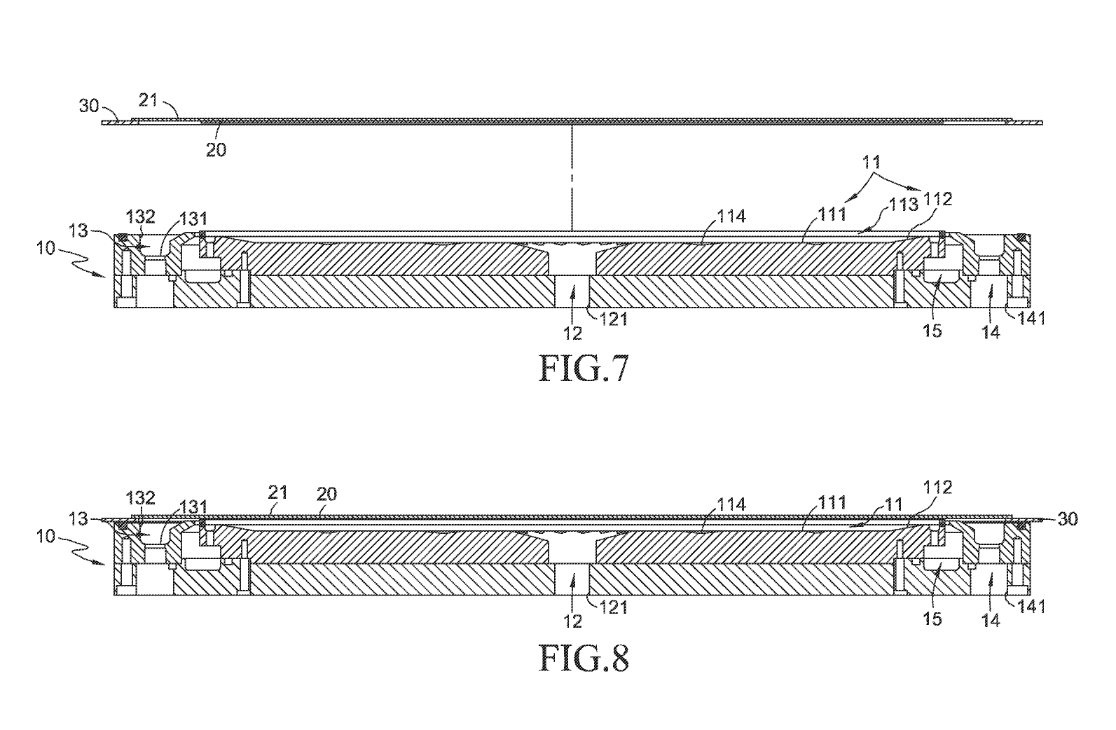

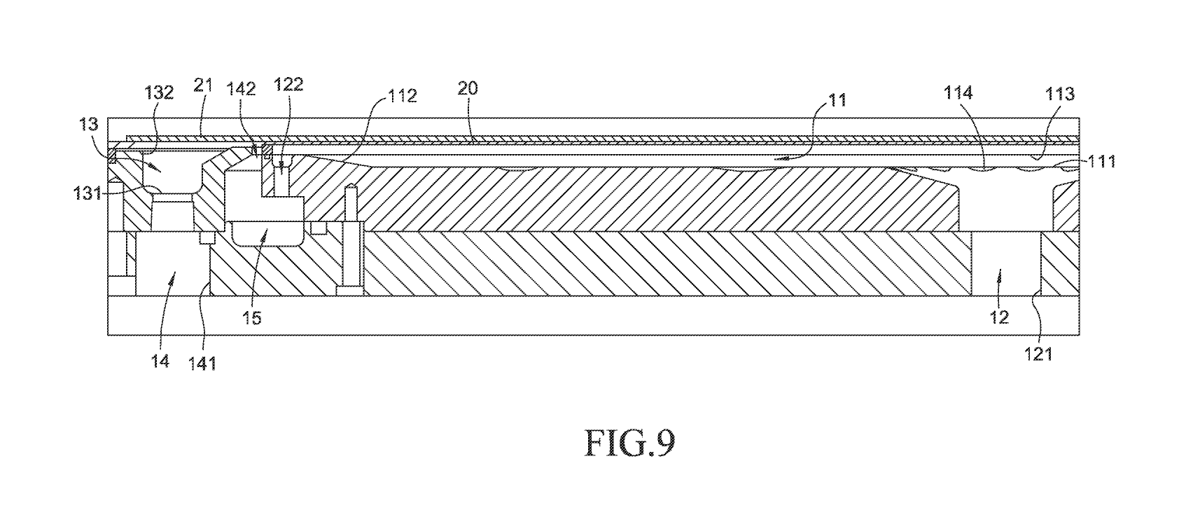

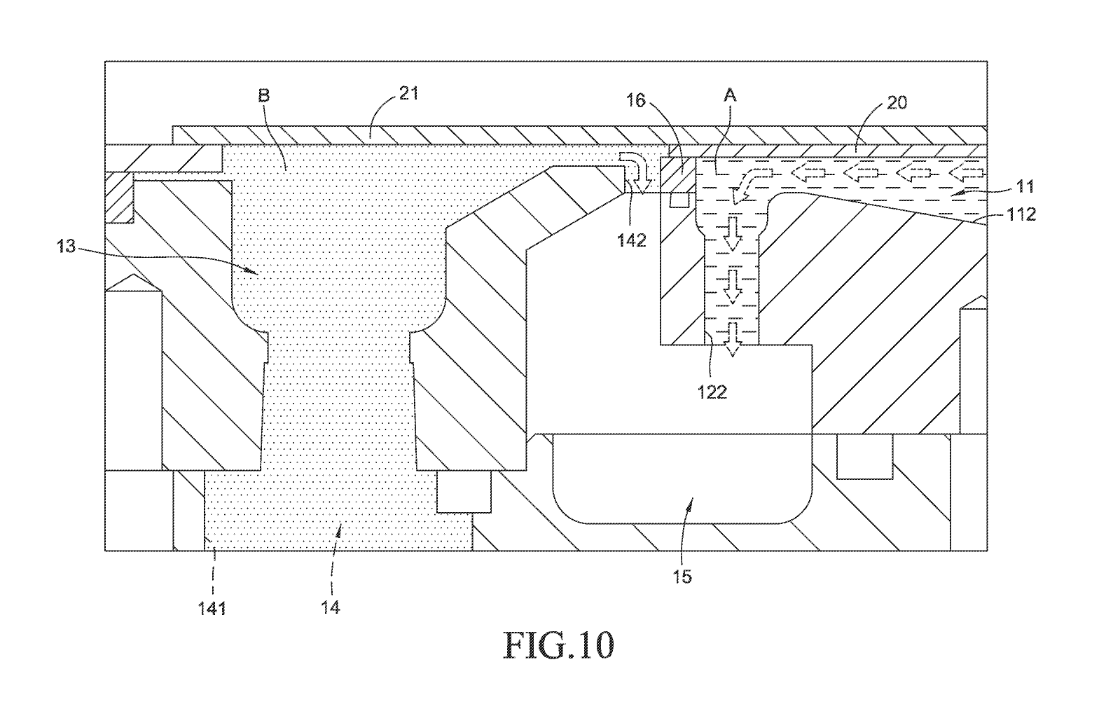

Please refer to FIGS. 6-10. FIG. 6 shows a schematic diagram of another whipsaw (despite sharing the same reference number with the whipsaw in FIG. 1) according to another embodiment of the present disclosure. FIGS. 7 and 8 are cross-sectional views of the whipsaw embodiment in FIG. 6. FIG. 9 is an enlarged view of a certain cross section of the whipsaw embodiment in FIG. 6. At the same time, FIG. 10 illustrates the cross section of the whipsaw embodiment in FIG. 6 when in use.

In the embodiment shown in FIG. 6, the whipsaw 10 may also include a cleaning tank 11, a first flow channel 12, an annular groove 13, a second flow channel 14, and a discharge chute 15. At least one aspect of the whipsaw embodiment in FIG. 6 differing from its counterpart in FIG. 1 is the lack of structural communication between the first outlet 122 of first flow channel 12 and the second outlet 142 of the second flow channel 14. Specifically, a blocking member 16 may be present between the first outlet 122 and the second outlet 142 for ensuring no communication between the first outlet 122 and the second outlet 142. When the frame 30 is placed in the whipsaw 10, the edge of the wafer 20 may align with the blocking member 16. As such, when the first fluid A flows out of the first outlet 122 and to the discharge chute 15 the first fluid A may not be in any physical contact with the edge of the wafer 20. Further coupled with the high-pressurized second fluid B, the first fluid A may not reach the tape 21 when flowing from the discharge chute 15 to the second outlet 142, effectively reducing the potential contamination or damage to the tape 21.

The whipsaw according to the present disclosure may enable the wafer and the tape to cover the whipsaw. As previously discussed, the wafer may mask the opening of the cleaning tank while the tape unmasked by the wafer may cover the notch of the annular groove. The first fluid when supplied at the high pressure may be therefore capable of effectively cleaning the surface of the wafer and may be recycled thereafter. The second fluid in the annular grove meanwhile may isolate the edge of the wafer from the first fluid, preventing the first fluid from contaminating or damaging the tape. Thus, the efficiency of the wafer cleaning may improve and the contamination or damage to the tape may be avoided.

Some modifications of these examples, as well as other possibilities will, on reading or having read this description, or having comprehended these examples, will occur to those skilled in the art. Such modifications and variations are comprehended within this disclosure as described here and claimed below. The description above illustrates only a relative few specific embodiments and examples of the present disclosure. The present disclosure, indeed, does include various modifications and variations made to the structures and operations described herein, which still fall within the scope of the present disclosure as defined in the following claims.

### MAJOR COMPONENT SYMBOL DESCRIPTION

10 Whipsaw
11 Cleaning tank
12 First flow channel
121 First inlet
122 First outlet
13 Annular groove
14 Second flow channel
141 Second inlet
142 Second outlet
15 Discharge chute
132 Notch
133 Stop surface
16 Blocking member
20 Wafer
21 Tape
30 Frame
31 Accommodating space
A First fluid
B Second fluid
111, Bottom surface
131
112 Guide slope
113 Opening
114 Guide groove
115 Beveled guide

What is claimed is:

1. A whipsaw for carrying a wafer in wafer cleaning, the wafer attached with a tape allowing for the wafer to be placed into a frame, the whipsaw comprising:
a cleaning tank;
an annular groove around a peripheral of the cleaning tank;
a discharge chute disposed between the cleaning tank and the annular groove;
at least one first flow channel communicative of the cleaning tank and the discharge chute; and
at least one second flow channel communicative of the annular groove and the discharge chute;
wherein the whipsaw is where the frame is placed, so that the wafer corresponds to the cleaning tank, a portion of the tape unmasked by the wafer corresponds to the annular groove, the first flow channel is for providing a first fluid into the cleaning tank, the first fluid is used for cleaning the wafer, the second flow channel is for providing a second fluid into the annular groove, and the second fluid is for isolating the first fluid from the tape.

2. The whipsaw according to claim 1, wherein the first flow channel comprises a first inlet formed within the cleaning tank and a first outlet communicative of the discharge chute, and the second flow channel comprises a second inlet formed within the annular groove and a second outlet communicative of the discharge chute and the first outlet.

3. The whipsaw according to claim 2, wherein the cleaning tank defines a bottom surface and a guide slope surrounding the bottom surface and has an opening formed at a side opposite from the bottom surface, with the opening selectively masked by the wafer, the first inlet formed at the bottom surface of the cleaning tank, and the first outlet formed at a terminal of the guide slope and communicative of the opening.

4. The whipsaw according to claim 3, wherein the cleaning tank is in a divergent shape beginning from the bottom surface to the opening.

5. The whipsaw according to claim 2, wherein the annular groove defines a bottom surface and notch disposed at a terminal opposite from the bottom surface, with the portion of tape unmasked by the wafer selectively covering the notch to form a tilt angle, the second inlet disposed in the annular groove, and the second outlet formed at the notch of the annular groove.

6. The whipsaw according to claim 1, wherein the first flow channel comprises a first inlet formed within the cleaning tank and a first outlet communicative of the discharge chute, and the second flow channel comprises a second inlet formed within the annular groove and a second outlet communicative of the discharge chute, with an isolating element preventing communication between the first outlet and the second outlet.

7. The whipsaw according to claim 6, wherein the cleaning tank defines a bottom surface and a guide slope surrounding the bottom surface and has an opening formed at a side opposite from the bottom surface, with the opening selectively masked by the wafer, the first inlet formed at the bottom surface of the cleaning tank, and the first outlet formed at a terminal of the guide slope and communicative of the opening.

8. The whipsaw according to claim 7, wherein the cleaning tank is in a divergent shape beginning from the bottom surface to the opening.

9. The whipsaw according to claim 7, further comprising a plurality of guide grooves disposed on the bottom surface and arranged in a radial direction from the first inlet.

10. The whipsaw according to claim 6, wherein the annular groove defines a bottom surface and notch disposed at a terminal opposite from the bottom surface, with the portion of tape unmasked by the wafer selectively covering the notch, the second inlet disposed in the annular groove, and the second outlet formed at the notch of the annular groove.
